(19) United States
(12) Patent Application Publication
(10) Pub. No.: US 2021/0305328 A1
(43) Pub. Date: Sep. 30, 2021

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Wenjing YU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/051,183

(22) PCT Filed: May 25, 2020
(86) PCT No.: PCT/CN2020/092121

§ 371 Date: Oct. 28, 2020

(30) Foreign Application Priority Data
Mar. 30, 2020 (CN) 202010238574.8

(51) Int. Cl. H01L 27/32; G06F 3/041

(52) U.S. Cl. CPC H01L 27/323; G06F 3/0412

(57) ABSTRACT

The present disclosure provides a display panel and a display device. The display panel uses a new structure design of a touch electrode layer to effectively reduce impedance of the touch electrode layer without affecting a light-emitting rate of the display panel.

### FIELD OF INVENTION

The present disclosure relates to the field of display technology, and more particularly to a display panel and a display device.

### BACKGROUND OF INVENTION

Today, active matrix organic light-emitting diode (AMOLED) display panels are more and more regarded by consumers. Among them, a touch panel (TP) is an important part of the AMOLED display panel. Because an external TP not only increases a thickness of the display panel, but also increases a weight of the display device, in order to meet the needs of consumers, a direct on-cell (DOT) TP technology was invented. The on-cell TP technology, as the name implies, directly dispose a TP film (ie touch electrode layer) on a thin film encapsulating layer. Such a design can not only prevent a problem of accurate alignment difference of the TP film layer, but also significantly reduce the thickness and weight of the display panel.

In the on-cell TP technology, if the TP film layer is disposed on the AMOLED light-emitting unit directly, it will affect a light-emitting rate of the display panel. In order to prevent the TP film layer from affecting the light-emitting rate of the display panel, the TP film layer is usually arranged in the middle of adjacent light-emitting units. If a brightness of the display panel is to be increased when a luminous efficiency of the luminescent material remains unchanged, an area of the luminous unit needs to be increased. In this way, a line width of the TP film needs to be reduced accordingly, which will increase impedance of the TP film.

In view of above statement, how to reduce the impedance of the TP film without affecting the light-emitting rate of the display panel has become a key research topic for related researchers and technicians.

### SUMMARY OF INVENTION

An object of the present disclosure is to provide a display panel and a display device. The display panel uses a new structure design of the touch electrode layer to effectively reduce an impedance of the touch electrode layer without affecting the light-emitting rate of the display panel.

According to an aspect of the present disclosure, the present disclosure provides a substrate;

an organic light-emitting layer disposed on the substrate, the organic light-emitting layer comprising a plurality of light-emitting units;

an encapsulation layer disposed on the organic light-emitting layer; and

a touch electrode layer disposed on the encapsulation layer, the touch electrode layer comprising a plurality of touch electrode units, each of the touch electrode units corresponds to each of the light-emitting units; each of the touch electrode layer comprising a hollow area having a shape is same as a shape of the light-emitting unit, and a boundary of an orthographic projection of the hollow area on a surface where the organic light-emitting layer located does not intersect boundaries of the light-emitting units; the orthographic projection of the hollow area on the surface where the organic light-emitting layer located is outside the light-emitting unit; the non-hollow areas in adjacent touch electrode units are connected to each other.

In at least one embodiment of the present disclosure, wherein the hollow area is one of a circle, an ellipse or a polygon.

In at least one embodiment of the present disclosure, wherein a distance between the boundary of the orthographic projection of the hollow area on the surface where the organic light-emitting layer located and the boundaries of the light-emitting units are set according to a material of the light-emitting unit.

In at least one embodiment of the present disclosure, wherein the touch electrode layer is made of opaque metal.

In at least one embodiment of the present disclosure, wherein the metal is one of aluminum, silver, or copper.

In at least one embodiment of the present disclosure, wherein the touch electrode layer is made of multilayer of a composite metal.

In at least one embodiment of the present disclosure, wherein the composite metal is a titanium aluminum titanium three-layer composite metal.

In at least one embodiment of the present disclosure, wherein the encapsulation layer comprises a first inorganic encapsulation layer, an organic encapsulation layer, and a second inorganic encapsulation layer stacked from bottom to top.

According to another aspect of the present disclosure, the present disclosure provides a display panel, which includes: a substrate;

an organic light-emitting layer disposed on the substrate, the organic light-emitting layer comprising a plurality of light-emitting units;

an encapsulation layer disposed on the organic light-emitting layer; and

a touch electrode layer disposed on the encapsulation layer, the touch electrode layer comprising a plurality of touch electrode units, each of the touch electrode units corresponds to each of the light-emitting units; each of the touch electrode layer comprising a hollow area having a shape is same as a shape of the light-emitting unit, and a boundary of an orthographic projection of the hollow area on a surface where the organic light-emitting layer is located does not intersect boundaries of the light-emitting units.

On the basis of the above technical solution, the following improvements can be made.

In at least one embodiment of the present disclosure, wherein the orthographic projection of the hollow area on the surface where the organic light-emitting layer located is outside the light-emitting unit.

In at least one embodiment of the present disclosure, wherein the hollow area is one of a circle, an ellipse or a polygon.

In at least one embodiment of the present disclosure, wherein the non-hollow areas in adjacent touch electrode units are connected to each other.

In at least one embodiment of the present disclosure, wherein a distance between the boundary of the orthographic projection of the hollow area on the surface where the organic light-emitting layer located and boundaries of the light-emitting units are set according to a material of the light-emitting unit.

In at least one embodiment of the present disclosure, wherein the touch electrode layer is made of opaque metal.

In at least one embodiment of the present disclosure, wherein the metal is one of aluminum, silver, or copper.

In at least one embodiment of the present disclosure, wherein the composite metal is a titanium aluminum titanium three-layer composite metal.

In at least one embodiment of the present disclosure, wherein the encapsulation layer comprises a first inorganic encapsulation layer, an organic encapsulation layer, and a second inorganic encapsulation layer stacked from bottom to top.

According to another aspect of the present disclosure, the present disclosure also provides a display device, which includes the above-mentioned display panel.

The advantage of the present disclosure is that the display panel of the present disclosure uses a new structure design of the touch electrode layer to effectively reduce the impedance of the touch electrode layer without affecting the light-emitting rate of the display panel.

### DESCRIPTION OF FIGURES

In order to more clearly explain the embodiments or the technical solutions in the prior art, the following will briefly introduce the figures required in the description of the embodiments or the prior art. Obviously, the figures in the following description are only for some embodiments of the present disclosure, those of ordinary skill in the art can obtain other figures based on these figures without any inventive steps.

FIG. 1 is a schematic diagram of a structure of a display panel in one embodiment of the present disclosure.

FIG. 2 is a schematic diagram of a relationship between a hollow area and a light-emitting unit in one embodiment of the present disclosure.

FIG. 3 is a schematic diagram of a relationship between a touch electrode unit and the light-emitting unit in the example described in one embodiment of the present disclosure.

FIG. 4 is a schematic diagram of a display device in one embodiment of the present disclosure.

### DETAILED DESCRIPTION OF PREFERRED EMBODIMENTS

The present disclosure provides a physical keyboard input system, keyboard input method, and storage medium. In order to make the purpose, technical solution, effect of the present disclosure clearer and more specifically. The present disclosure described in detail below with reference to the accompanying figures and examples. It should be understood specific embodiments described herein are only explained and not to limit the present disclosure.

The technical solutions in the embodiments of the present disclosure will be clearly and completely described below in conjunction with the figures in the embodiments of the present disclosure. Obviously, the described embodiments are only a part of the embodiments of the present disclosure, rather than all the embodiments. Based on the embodiments in the present disclosure, all other embodiments obtained by those skilled in the art without inventive steps within the protection scope of the present disclosure.

The terms “first”, “second”, “third”, etc. (if any) in the description and claims of the present disclosure and the above-mentioned figures are used to distinguish similar objects, and not necessarily used to describe a specific order. It should be understood that the objects described in this way can be interchanged under appropriate circumstances. In addition, the terms “including” and “having” and any variations of them are intended to cover non-exclusive inclusion.

In the present disclosure, the accompanying figures discussed below and various embodiments used to describe the principles disclosed in the present disclosure are for illustration only, and should not be construed as limiting the scope of the present disclosure. Those skilled in the art will understand that the principles of the present disclosure can be implemented in any suitably arranged system. Exemplary embodiments will be described in detail, and examples of these embodiments are shown in the figures. In addition, a terminal according to an exemplary embodiment will be described in detail with reference to the accompanying figures. The same reference numerals in the figures refer to the same elements.

The terms used in the specification of the present disclosure are only used to describe specific implementations, and are not intended to show the concept of the present disclosure. Unless there is a clearly different meaning in the context, the expression used in the singular form encompasses the expression in the plural form. In the specification of the present disclosure, it should be understood that terms such as “including”, “having”, and “containing” are intended to indicate the possibility of the features, numbers, steps, actions, or combinations thereof disclosed in the specification of the present disclosure, but the possibility that one or more other features, numbers, steps, actions or combinations thereof may exist or may be added is not excluded. The same reference numerals in the figures refer to the same parts.

The embodiment of the present disclosure provides a display panel. The detailed description will be provided below.

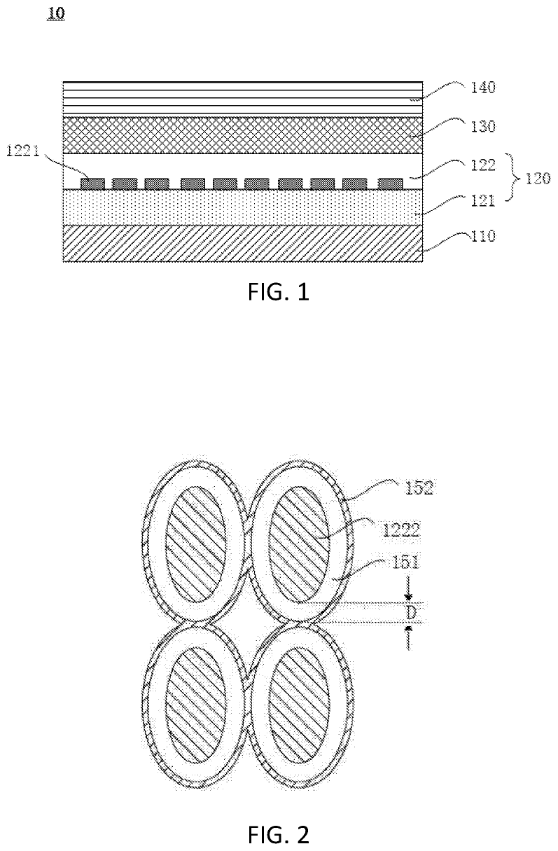

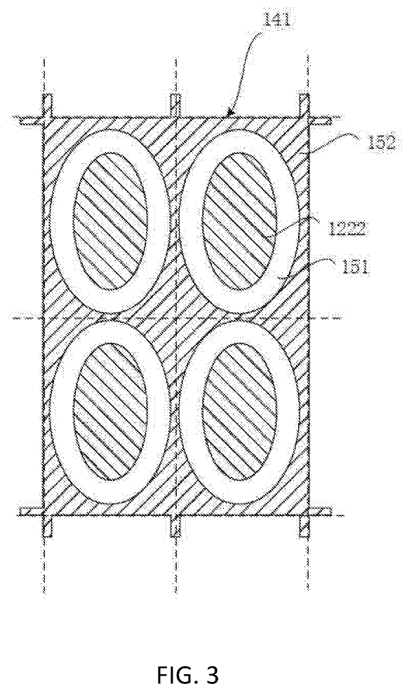

For ease of understanding, the present disclosure will be described in conjunction with the accompanying figures. Please refer to FIG. 1 to FIG. 3. FIG. 1 is a schematic diagram of the structure of a display panel in one embodiment of the present disclosure. FIG. 2 is a schematic diagram of the relationship between the hollow area and the light-emitting unit in the embodiment of the present disclosure. FIG. 3 is a schematic diagram of a relationship between the touch electrode unit and the light-emitting unit in the example described in one embodiment of the present disclosure.

As shown in FIG. 1, the display panel 100 shown in the present disclosure includes a substrate 110, an organic light-emitting layer 122, an encapsulation layer 130, and a touch electrode layer 140 that are stacked.

The substrate 110 may be a touch substrate, or may be an array substrate or a counter substrate with a touch function, or may be a display substrate with a touch function. Of course, the touch substrate can also be a flexible substrate.

In the substrate provided by at least one embodiment of the present disclosure, the substrate 110 may include a display structure layer, and the display structure layer further includes a driving array layer 121 (or a TFT layer) and a light-emitting structure layer, here is an organic light-emitting layer 122, namely the OLED layer.

The organic light-emitting layer 122 may include a pixel define layer (PDL) and a sub-pixel area defined by the pixel define layer. Each sub-pixel area from a side close to the driving array layer 121 to a side far away from the driving array layer 121 may include an anode layer, a light-emitting layer, and a cathode layer (not shown) in sequence. In a specific embodiment, the anode is an ITO (Indium Tin Oxide)/Ag/ITO three-layer structure with high work function and high reflectivity, and the cathode is a metal Mg/Ag alloy with low work function.

The encapsulation layer 130 is disposed on the organic light-emitting layer 122. The encapsulation layer 130 may have a single-layer structure or a composite structure of at least two layers. For example, the material of the encapsulation layer 130 may include insulating materials such as silicon nitride, silicon oxide, silicon oxynitride, and polymer resin. For another example, the encapsulation layer 130 may include a first inorganic encapsulation layer, an organic encapsulation layer, and a second inorganic encapsulation layer. The materials of the first inorganic encapsulation layer and the second inorganic encapsulation layer may include inorganic materials, such as silicon nitride, silicon oxide, silicon oxynitride, etc. The inorganic materials have high density and can prevent the intrusion of water, oxygen, and the like. The material of the organic encapsulation layer can be a polymer material containing a desiccant or a polymer material that can block water vapor, such as polymer resin to planarize the surface of the display substrate, and can relieve a stress of the first inorganic encapsulation layer and the first inorganic encapsulation layer, and may also include water-absorbing materials, such as desiccant to absorb substances such as water and oxygen that have penetrated inside.

The touch electrode layer 140 is disposed on the encapsulation layer 130, and the touch electrode layer 140 is patterned to ensure that a light emitted by the organic light-emitting layer 122 can normally pass through. The touch electrode layer 140 may be an opaque electrode or a transparent electrode. The material of the opaque electrode is an opaque metal, such as silver, aluminum, or copper.

The touch electrode layer 140 can also be made of a multilayer composite metal, preferably a titanium-aluminum-titanium three-layer composite metal, which can prevent metal oxidation and enhance the bending resistance of the trace of the touch electrode layer performance. Of course, it is not limited to the titanium-aluminum-titanium three-layer composite metal, and molybdenum-aluminum-molybdenum can also be used.

In this embodiment, the organic light-emitting layer 122 includes a plurality of sub-pixels 1221 arranged at intervals, wherein the sub-pixels 1221 are red, green, and blue (RGB) sub-pixels.

Since the organic light-emitting layer 122 includes a plurality of light-emitting units 1222, and each light-emitting unit 1222 corresponds to each of the sub-pixels 1221, the light-emitting units 1222 can also be regarded as being arranged at intervals.

In this embodiment, the touch electrode layer 140 includes a plurality of touch electrode units 141, and each of the touch electrode units 141 corresponds to each of the light-emitting units 1222.

In order to prevent the touch electrode layer 140 from affecting the light-emitting rate of the display panel 10, the touch electrode layer 140 is usually arranged in a middle of the adjacent light-emitting unit 1222. That is an orthographic projection of the touch electrode unit 1222 on a surface where the organic light-emitting layer 122 located is located between each adjacent light-emitting unit 1222.

If a trace width of the touch electrode layer 140 is set to be narrow, there may be problems in the process that cannot be implemented specifically, and according to the resistance definition formula, it can be known that an resistance greater when an cross-sectional area (here, the trace width) of the resistor smaller. Therefore, this configuration will increase an impedance of the touch electrode layer 140.

If the trace width of the touch electrode layer 140 is set to be wider, the light and brightness of the light-emitting unit 1222 will be affected, that is, the light-emitting rate of the display panel 10 will be affected.

Therefore, in the present disclosure, using the new structure design of the touch electrode layer 140 not only ensured the light-emitting rate of the display panel, but also reduced an impedance of the touch electrode layer 140 effectively.

As shown in FIG. 3, the specific design is as follows: each touch electrode unit 141 includes a hollow area 151. A boundary of an orthographic projection of the hollow area 151 on a surface where the organic light-emitting layer 122 located does not intersect boundaries of the light-emitting units 1222.

A shape of the hollow area 151 can be any one of a circle, an ellipse and a polygon.

Furthermore, an orthographic projection of the hollow area 151 on the surface where the organic light-emitting layer 122 located is outside the light-emitting unit 1222. That is, the orthographic projection of the hollow area 151 on the surface where the organic light-emitting layer 122 located is larger than the light-emitting unit 1222, which can ensure that the touch electrode unit 141 will not block the light-emitting unit 1222.

Since an orthographic projection of the hollow area 151 on the surface where the organic light-emitting layer 122 located is outside the light-emitting unit 1222, a certain distance D between the boundary of the orthographic projection of the hollow area 151 on the surface where the organic light-emitting layer 122 and boundaries of the light-emitting units 1222, as shown in FIG. 2.

The distance D should not be set too narrow or too wide. If the distance D is too narrow, it may still affect the light and brightness of the light-emitting unit 1222 to a certain extent. If the distance D is too wide, although the light and brightness of the light-emitting unit 1222 will not be affected, the non-hollow area 152 in the touch electrode unit 141 which surrounds the hollow area 151 will be reduced a certain extent, an impedance of the touch electrode unit 141 is further affected. Therefore, in order to ensure the reasonable setting of the distance D, the shape of the hollow area 151 and the shape of the light-emitting unit 1222 need to be designed to be the same.

In addition, the distance D between the boundary of the orthographic projection of the hollow area 151 on the surface where the organic light-emitting layer 122 located and the boundaries of the light-emitting units 1222 are set according to a material of the light-emitting unit 1222.

In the embodiment of the present disclosure, preferably, the non-hollow areas 152 in adjacent touch electrode units 141 are connected to each other. In this way, the non-hollow area 152 (that is, the trace width of the touch electrode) in the touch electrode unit 141 can be maximized. Since the touch electrode layer 140 is made of metal, the impedance of the touch electrode layer 140 can be further reduced to achieve the purpose of energy saving.

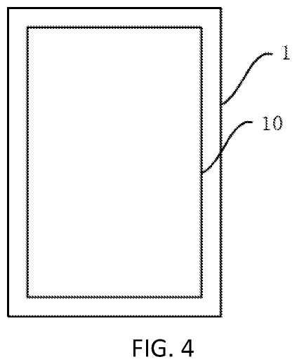

In addition, as shown in FIG. 4, the present disclosure also provides a display device 1 which includes the above-mentioned display panel 10. The specific structure of the display panel 10 is as described above, and will not be repeated here. The display device 1 can be any product or component with a display function, such as a mobile phone, a tablet computer, a television, a monitor, a notebook computer, a digital photo frame, a navigator, and the like.

The advantage of the present disclosure is that the display panel 10 of the present disclosure uses a new wiring design of the touch electrode layer to effectively reduce the impedance of the touch electrode layer without affecting the light-emitting rate of the display panel 10.

The above are only the preferred embodiments of the present disclosure. It should be pointed out that for those of ordinary skill in the art, without departing from the principles of the present disclosure, several improvements and modifications can be made, and these improvements and modifications should also be considered the protection scope of the present disclosure.

What is claimed is:

1. A display panel, comprising:
a substrate;
an organic light-emitting layer disposed on the substrate, the organic light-emitting layer comprising a plurality of light-emitting units;
an encapsulation layer disposed on the organic light-emitting layer; and
a touch electrode layer disposed on the encapsulation layer, the touch electrode layer comprising a plurality of touch electrode units, one of the touch electrode units corresponds to each of the light-emitting units; each of the touch electrode units comprising a hollow area having a shape is same as a shape of one of the light-emitting units, a boundary of an orthographic projection of the hollow area on a surface where the organic light-emitting layer is located does not intersect boundaries of the light-emitting units; the orthographic projection of the hollow area on the surface where the organic light-emitting layer located is outside the light-emitting units; and non-hollow areas of adjacent touch electrode units are connected to each other.

2. The display panel as claimed in claim 1, wherein the hollow area is one of a circle, an ellipse, or a polygon.

3. The display panel as claimed in claim 1, wherein a distance between the boundary of the orthographic projection of the hollow area on the surface where the organic light-emitting layer located and the boundaries of the light-emitting units are set according to a material of the light-emitting units.

4. The display panel as claimed in claim 1, wherein the touch electrode layer is made of opaque metal.

5. The display panel as claimed in claim 4, wherein the metal is one of aluminum, silver, or copper.

6. The display panel as claimed in claim 4, wherein the touch electrode layer is made of multilayer of a composite metal.

7. The display panel as claimed in claim 6, wherein the composite metal is a titanium aluminum titanium three-layer composite metal.

8. The display panel as claimed in claim 1, wherein the encapsulation layer comprises a first inorganic encapsulation layer, an organic encapsulation layer, and a second inorganic encapsulation layer stacked from bottom to top.

9. A display panel, comprising:
a substrate;
an organic light-emitting layer disposed on the substrate, the organic light-emitting layer comprising a plurality of light-emitting units;
an encapsulation layer disposed on the organic light-emitting layer; and
a touch electrode layer disposed on the encapsulation layer, the touch electrode layer comprising a plurality of touch electrode units, each of the touch electrode units corresponds to each of the light-emitting units; each of the touch electrode layer comprising a hollow area having a shape is same as a shape of the light-emitting unit, and a boundary of an orthographic projection of the hollow area on a surface where the organic light-emitting layer located does not intersect boundaries of the light-emitting units.

10. The display panel as claimed in claim 9, wherein the orthographic projection of the hollow area on the surface where the organic light-emitting layer located is outside the light-emitting unit.

11. The display panel as claimed in claim 9, wherein the hollow area is one of a circle, an ellipse or a polygon.

12. The display panel as claimed in claim 9, wherein the non-hollow areas in adjacent touch electrode units are connected to each other.

13. The display panel as claimed in claim 9, wherein a distance between the boundary of the orthographic projection of the hollow area on the surface where the organic light-emitting layer located and the boundaries of the light-emitting units are set according to a material of the light-emitting unit.

14. The display panel as claimed in claim 9, wherein the touch electrode layer is made of opaque metal.

15. The display panel as claimed in claim 14, wherein the metal is one of aluminum, silver, or copper.

16. The display panel as claimed in claim 14, wherein the touch electrode layer is made of multilayer of a composite metal.

17. The display panel as claimed in claim 9, wherein the encapsulation layer comprises a first inorganic encapsulation layer, an organic encapsulation layer, and a second inorganic encapsulation layer stacked from bottom to top.

18. A display device, wherein the display device comprises the display panel as claimed in claim 9.
